(19) United States
(12) Patent Application Publication
(10) Pub. No.: US 2023/0063909 A1
(43) Pub. Date: Mar. 2, 2023

(54) GRINDING CONTROL METHOD, GRINDING CONTROL APPARATUS AND STORAGE MEDIUM

(71) Applicant: CHANGXIN MEMORY TECHNOLOGIES, INC., Hefei City, Anhui (CN)

(72) Inventors: Jinghao WANG, Hefei City, Anhui (CN); Yu BAO, Hefei City, Anhui (CN)

(21) Appl. No.: 17/599,448

(22) PCT Filed: Jun. 1, 2021
(86) PCT No.: PCT/CN2021/097665

§ 371 Date: Sep. 28, 2021

(30) Foreign Application Priority Data
Oct. 14, 2020 (CN) 202011094938.6

(51) Int. Cl. B24B 37/013; H01L 21/66; H01L 21/321

(52) U.S. Cl. CPC B24B 37/013; H01L 22/26; H01L 21/3212

(57) ABSTRACT

The present application provides a grinding control method, a grinding control apparatus and a storage medium, and is applied in the field of semiconductor manufacturing processes. The method includes: acquiring a target resistance value of a metal film of a grinding object set by a user, determining a target output value of an eddy current sensor according to the target resistance value, acquiring an output value of the eddy current sensor in real time, and stopping a grinding task when the output value reaches the target output value.

### CROSS-REFERENCE TO RELATED APPLICATIONS

The present application is a national stage entry under 35 U.S.C. § 371 of International Application No. PCT/CN2021/097665, filed on Jun. 1, 2021, which claims the priority to Chinese Patent Application No. 202011094938.6, titled “GRINDING CONTROL METHOD, GRINDING CONTROL APPARATUS AND STORAGE MEDIUM”, filed to the CNIPA on Oct. 14, 2020. The entire contents of International Application No. PCT/CN2021/097665 and Chinese Patent Application No. 202011094938.6 are incorporated herein by reference.

### TECHNICAL FIELD

The present application relates to the technical field of semiconductors, and in particular to a grinding control method, a grinding control apparatus and a storage medium.

### BACKGROUND

With the rapid development of semiconductor industry and the size reduction of electronic devices, wafer surfaces are required to have good flatness. Conventional planarization technologies can only realize local planarization, but global planarization is required when the minimum feature size is below 0.25 μm. The chemical mechanical polishing (CMP) technology is a common technology to realize global planarization.

The CMP technology is a process technology that smoothens the metal membrane on the surface of the integrated circuit device and makes the metal film become highly flat by organically combining the physical grinding action of nanoscale particles and the chemical corrosion action of the polishing solution. In the current CMP technology, the grinding time of the process of planarizing the rough surface of the metal membrane is mainly controlled by the following two schemes. One scheme is to fix the grinding time to obtain the constant metal removal amount, while the other scheme is to adjust the CMP grinding time by a run to run (R2R) control system and measurement means to obtain the constant remain thickness of the metal film.

However, the two schemes have the following problems: the thickness of the metal membrane after the CMP process cannot be constant completely, so that the resistance value of the metal membrane in the semiconductor device will fluctuate due to the difference in thickness of the metal film and the stability of the overall performance of the device is affected.

### SUMMARY

In a first aspect, an embodiment of the present application provides a grinding control method, comprising:

acquiring a target resistance value of a metal film of a grinding object set by a user;

determining a target output value of an eddy current sensor according to the target resistance value; and

acquiring an output value of the eddy current sensor in real time, and stopping a grinding task when the output value reaches the target output value.

In a second aspect, an embodiment of the present application provides a grinding control apparatus, comprising:

an acquisition module, configured to acquire a target resistance value of a metal film of a grinding object set by a user; and

a processing module, configured to determine a target output value of an eddy current sensor according to the target resistance value; and

the acquisition module is further configured to acquire an output value of the eddy current sensor in real time, and the processing module is further configured to stop a grinding task when the output value reaches the target output value.

In a third aspect, an embodiment of the present application provides a grinding control apparatus, comprising:

at least one processor; and

a memory communicatively connected to the at least one processor, wherein,

the memory is stored with instructions executable by the at least one processor that, when executed by the at least one processor, enable the grinding control apparatus to execute the method described in the first aspect of the present application.

### BRIEF DESCRIPTION OF THE DRAWINGS

FIG. 1 is a schematic structure diagram of a grinding apparatus according to an embodiment of the present application;

FIG. 2 is a schematic diagram of an operation flow of a R2R system according to an embodiment of the present application;

FIG. 3 is a flowchart of a grinding control method according to an embodiment of the present application;

FIG. 4 is a flowchart of generating a fitted curve of the resistance value of the metal film of the grinding object and the output value of the eddy current sensor according to an embodiment of the present application;

FIG. 5 is a graph of the sensed voltage value of the eddy current sensor and the grinding time according to an embodiment of the present application;

FIG. 6 is a graph of fitting curve of the resistance values of the metal films of the grinding objects and the sensed voltage values of the eddy current sensor according to an embodiment of the present application;

FIG. 7 is a schematic diagram of the distribution of the resistance value of the grinding object obtained by fixing the grinding time and automatically adjusting the grinding time in the present application;

FIG. 8 is a schematic structure diagram of a grinding control apparatus according to an embodiment of the present application; and

FIG. 9 is a schematic diagram of the hardware structure of a grinding control apparatus according to an embodiment of the present application.

### DETAILED DESCRIPTION

The technical solutions in the embodiments of the present application will be described clearly and completely with reference to the drawings in the embodiments of the present application. Apparently, the embodiments to be described are only some but not all of the embodiments of the present application. Based on the embodiments of the present application, all other embodiments obtained by a person of ordinary skill in the art without paying any creative effort shall fall into the protection scope of the present application.

It is to be noted that, the terms “first”, “second” or the like used in the specification, claims and drawings of the present application are used for distinguishing similar objects, rather than describing a particular order or sequence. It should be understood that the data used in such a way may be interchanged if appropriate, so that the embodiments of the present application described herein can be implemented in an order other than those illustrated or described herein.

In addition, the terms “comprise/comprising” and “having” and any variants thereof are intended to encompass an exclusive inclusion. For example, a process, method, system, product or device comprising a series of steps or units is not limited to the steps or units that are listed explicitly, and may comprise other steps or units that are not listed explicitly or inherent to the process, method, product or device.

The technical solutions provided in the embodiments of the present application relates to a process for manufacturing a semiconductor memory, and in particular to a planarization process for a rough surface of a metal film after coating during the production of a dynamic random access memory (DRAM).

With the rapid development of semiconductor industry and the size reduction of electronic devices, the flatness of wafer surfaces is required to reach a nanometer level. Conventional planarization technologies can only realize local planarization, but global planarization is required when the minimum feature size is below 0.25 μm. At present, the technology that can realize global planarization is chemical mechanical polishing (CMP). The CMP smoothens silicon slices (silicon wafers) or other substrate materials during machining by a chemical corrosion and a mechanical force.

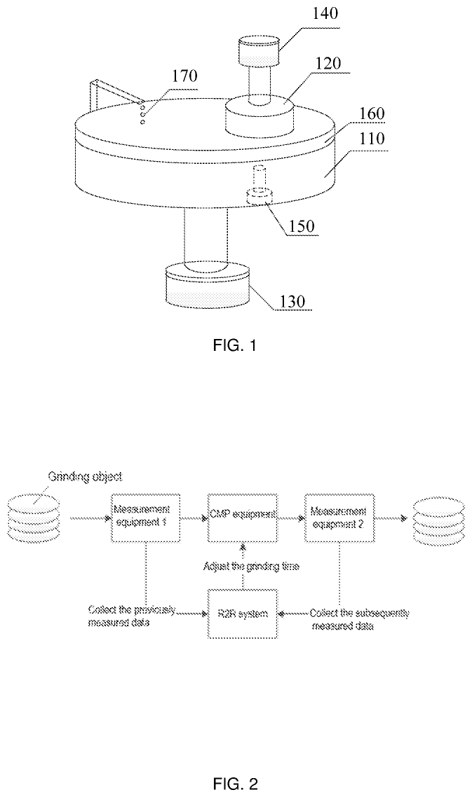

Exemplarily, FIG. 1 is a schematic structure diagram of a grinding apparatus according to an embodiment of the present application. As shown in FIG. 1, the grinding apparatus in this embodiment comprises: a grinding table 110, a grinding head 120, a first motor 130 for driving the grinding table 110 to rotate, a second motor 140 for driving the grinding head 120 to rotate, and an eddy current sensor 150.

A grinding pad 160 (also referred to as a polishing pad) is mounted on the upper surface of the grinding table 110. The grinding pad 160 is made of a loose and porous material with certain elasticity, usually polyurethane, and mainly functions to store and transport a grinding solution 170 (also referred to as a polishing solution) and provides a certain pressure to a grinding object (e.g., a silicon wafer or other substrates, or various films formed on the surface of the substrate) so as to mechanically rub the surface of the grinding object. Since the grinding pad 160 has sponge-like mechanical characteristics and porous characteristics, and the grinding pad 160 has special trenches formed on its surface, the polishing uniformity can be improved.

The eddy current sensor 150 is arranged in a hole formed on the grinding table 110, and detects the thickness of the metal film of the grinding object along the grinding surface with the rotation of the grinding table 110. The eddy current sensor 150 is a non-contact sensor, and the coil of the eddy current sensor senses the eddy current on and near the surface of the detected material through current change. The eddy in the detected material (e.g., the metal film of the grinding object) also products its own magnetic field to react on the coil of the eddy current sensor. The eddy current sensor 150 collects and processes the data of the magnetic field of the detected material acting on the eddy current sensor 150. Thus, a voltage signal curve of the metal film over the grinding time can be obtained through data processing and simulation by a computer in the CMP equipment, so that the change in thickness of the grinded metal film can be indirectly reflected.

As shown in FIG. 1, the grinding object is fixed in the lowest part of the grinding head 120, and the grinding pad 160 is placed on the grinding table 110. During the grinding process, the rotating grinding head 120 presses on the rotating grinding pad 160 at a certain pressure, and the grinding solution 170 composed of submicron or nano grinding particles and a chemical solution flows between the surface of the grinding object and the grinding pad 160. Then, due to the transportation by the grinding pad 160 and the centrifugal force, the grinding solution 170 is uniformly distributed on the grinding pad 160, thereby forming a grinding solution film between the grinding object and the grinding pad 160. The chemical components in the grinding solution 170 chemically react with the surface material of the grinding object to convert insoluble substances into easily soluble substances or soften substances with a high hardness. Then, these chemical reactants are removed from the surface of the grinding object by the micromechanical friction of the grinding particles, and dissolved in the flowing liquid to be taken away. That is, planarization is realized during alternate chemical film removal and mechanical film removal processes.

It can be known from the above description that the CMP reaction is divided into the following two processes: a chemical process in which the chemicals in the grinding solution 170 chemically react with the surface of the grinding object to generate substances that are easily removed; and, a physical process in which the grinding particles in the grinding solution 170 mechanically and physically rub against the surface material of the grinding object to remove the substances generated by the chemical reaction.

Based on the above grinding apparatus, in the current CMP technology, the end point of the grinding time of the process of planarizing the rough surface of the metal film is mainly controlled by the following two schemes. One scheme is to fix the grinding time to obtain the constant metal remove amount, while the other scheme is to adjust the CMP grinding time by a run to run (R2R) control system and measurement means to obtain the constant remain thickness of the metal film.

FIG. 2 is a schematic diagram of the operation flow of the R2R system according to an embodiment of the present application. As shown in FIG. 2, the grinding object successively passes through a measurement equipment 1, a CMP equipment and a measurement equipment 2. The measurement equipment 1 is configured to measure the thickness of the metal film of the grinding object before the CMP process, and the measurement equipment 2 is configured to measure the thickness of the metal film of the grinding object after the CMP process. The R2R system randomly collects the previously measured thickness data of a certain number of grinding objects (e.g., 1 to 2 grinding objects) on the measurement equipment 1 and the subsequently measured thickness data of the grinding objects on the measurement equipment 2, acquires the grinding time, and adjusts the grinding time for a next batch of grinding objects according to the difference between the previously measured data and the subsequently measured data of a certain number of grinding objects. The previously measured thickness data refers to the thickness value of the grinding object before the CMP grinding process, and the subsequently measured thickness data refers to the thickness value of the grinding object after the CMP grinding process.

Although the way of fixing the grinding time to control the remove amount of the metal film in the CMP is simple, the thickness of the metal film after CMP will be affected by the fluctuation of the front-layer metal deposition process and the service life of consumables of the CMP equipment, and the remain thickness of the metal membrane after CMP cannot actually be constant completely, so that the resistance value of the metal film in the semiconductor device will fluctuate due to the difference in thickness of the metal membrane, and the overall performance is unstable.

The way of adjusting the grinding time by the R2R system and the measurement means is to obtain the stable remain thickness of the metal membrane after CMP. However, this way is heavily dependent on the measurement precision and the intelligence of the R2R system and limited by cost and efficiency, so it is unable to measure each wafer before and after CMP, and it is unable to automatically regulate the grinding time for each wafer during CMP. Thus, there is a different in the thickness of the metal membrane after the actual CMP process, the resistance of the metal film in the device will directly fluctuate, and the overall performance is unstable.

In view of the above problems, an embodiment of the present application provides a grinding control method. A simulation curve of the resistance value of the metal film of the grinding object and the output value of the eddy current sensor is obtained by multiple experiments. In the actual CMP manufacturing process, by performing identification and data processing on the eddy current signal of the metal film of the grinding object by the CMP equipment, the final voltage signal value corresponding to the target resistance value of the metal film set by the user can be obtained according to the simulation curve. The CMP equipment can automatically control the grinding time of the metal film processing process according to the final voltage signal value, so as to control the size of the resistance (RS) of the metal film in the semiconductor device. The metal films of a large amount of grinding objects produced by the method are small in resistance fluctuation and high in precision.

It is to be noted that the metal film (i.e., metal membrane) of the grinding object comprises conductive metals such as tungsten, copper and tantalum, and this will not be limited in the embodiments of the present application.

The technical solutions of the present application will be described below in detail by specific embodiments. The following specific embodiments may be combined with each other, and the same or similar concepts or processes may not be repeated in some embodiments.

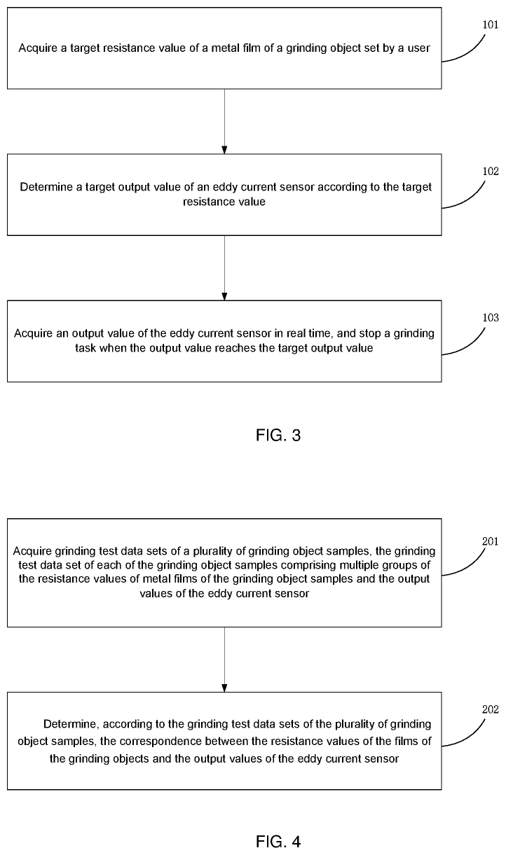

FIG. 3 is a flowchart of a grinding control method according to an embodiment of the present application. As shown in FIG. 3, the grinding control method in this embodiment comprises the following steps.

Step 101: A target resistance value of a metal film of a grinding object set by a user is acquired.

In one embodiment of the present application, the user can set the target resistance value of the metal film of the grinding object on the CMP equipment, so that the resistance values of the metal films of the grinding objects after the CMP process can reach this target resistance value.

In one embodiment of the present application, the user can also set the target thickness of the metal film of the grinding object on the CMP equipment, so that the thicknesses of the metal films of the grinding objects after the CMP process can reach this target thickness value. For a grinding object with a fixed size, there is a correspondence between the thickness and resistance value of the metal film of the grinding object, and the CMP equipment can acquire the target resistance value of the metal film of the grinding object according to the correspondence between the thickness and resistance value of the metal film of the grinding object and the target thickness set by the user.

The grinding object in this embodiment may be a wafer or other objects having meal films on their surfaces, and this will not be limited in the embodiments of the present application.

Step 102: A target output value of an eddy current sensor is determined according to the target resistance value.

In one embodiment of the present application, the step 102 specifically comprises:

acquiring a correspondence between the resistance values of the metal films of the grinding objects and the output values of the eddy current sensor; and

The target output value of the eddy current sensor is determined according to the correspondence between the resistance values of the metal films of the grinding objects and the output values of the eddy current sensor and the target resistance value of the metal film of the grinding object set by the user.

The correspondence between the resistance values of the metal films of the grinding objects and the output values of the eddy current sensor can be represented by a fitted curve. In practical applications, a graph of fitting curve of the resistance value of the metal film of the grinding object and the output value of the eddy current sensor is firstly acquired, the target output value of the eddy current sensor is then determined according to the graph of fitting curve and the target resistance value of the metal film of the grinding object set by the user, and the target output value is used as a monitoring point for stopping grinding.

Specifically, the graph of fitting curve of the resistance values of the metal films of the grinding objects and the output values of the eddy current sensor may be determined by grinding test data sets of a plurality of grinding object samples. The determination process may refer to FIG. 4.

FIG. 4 is a flowchart of generating the fitted curve of the resistance values of the metal films of the grinding objects and the output values of the eddy current sensor according to an embodiment of the present application. As shown in FIG. 4, the process comprises the following steps.

Step 201: Grinding test data sets of a plurality of grinding object samples are acquired, the grinding test data set of each of the grinding object samples comprising multiple groups of the resistance values of metal film of the grinding object sample and the output values of the eddy current sensor. The output value of the eddy current sensor comprises a sensed voltage value.

By taking a certain grinding object sample as an example, the grinding object sample is fixed between the grinding head and the grinding pad of the grinding table, the grinding duration is set, and the output value (e.g., sensed voltage value) of the eddy current sensor at the end of grinding is acquired by the CMP equipment. Meanwhile, the resistance value of the metal film of the grinding object at the end of grinding is acquired by a resistance measurement equipment (a WAT equipment that is different from the measurement equipment shown in FIG. 2), and the output value of the eddy current sensor and the resistance value of the metal film of the grinding object at the end of grinding are used as a group of test data.

Optionally, for a certain grinding object sample, multiple groups of test data may be acquired during the grinding process. Generally, the grinding duration is set as 20 s to 1 min. For example, the grinding duration is set as 1 min. When grinding is performed for 15 s, 30 s and 45 s, respectively, the output value of the eddy current sensor and the resistance value of the metal film of the grinding object are acquired to obtain multiple groups of measured data.

During acquiring grinding test data sets of a plurality of grinding object samples, different grinding durations may be set for different grinding object samples.

Step 202: The correspondence between the resistance values of the metal films of the grinding objects and the output values of the eddy current sensor are determined according to the grinding test data sets of the plurality of grinding object samples.

The grinding test sets of the grinding object samples comprise multiple groups of the output values of the eddy current sensor and the resistance values of the metal films of the grinding objects, and the correspondence between the output values of the eddy current sensor and the resistance values of the metal films of the grinding objects is determined according to the multiple groups of the output values of the eddy current sensor and the resistance values of the metal films of the grinding objects. That is, the graph of fitting curve of the output values of the eddy current sensor and the resistance values of the metal films of the grinding objects.

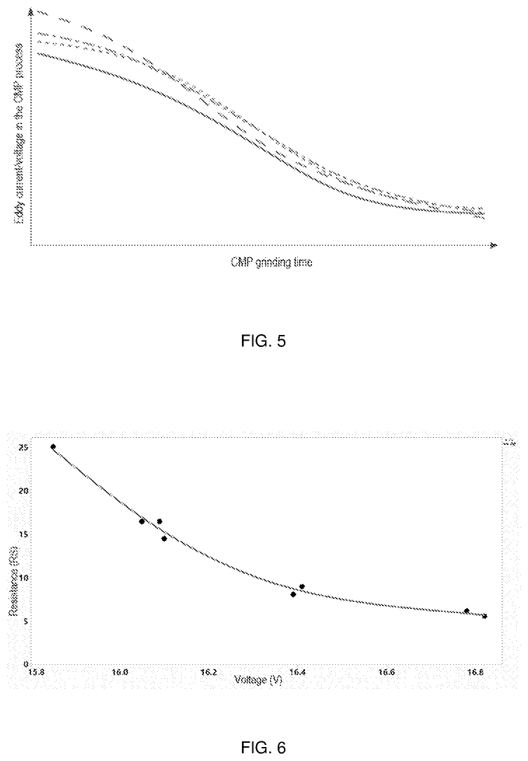

Exemplarily, FIG. 5 is a graph of the sensed voltage value of the eddy current sensor and the grinding time according to an embodiment of the present application. FIG. 5 shows multiple curves, which represent change charts of the sensed voltage of the eddy current sensor over time during the grinding process of different grinding object samples, respectively. It can be known from FIG. 5 that the correspondence between the sensed voltage value of the eddy current sensor and the grinding time is in an inverse proportional function relationship. That is, the longer the grinding time is, the smaller the sensed voltage value of the eddy current sensor is. It can be known that, if different grinding durations are set for a certain grinding object sample, the corresponding sensed values of the eddy current sensor are different.

Exemplarily, FIG. 6 is a graph of fitting curve of the resistance values of the metal films of the grinding objects and the sensed voltage values of the eddy current sensor according to an embodiment of the present application. It can be known from FIG. 6 that the correspondence between the resistance values of the metal films of the grinding objects and the sensed voltage values of the eddy current sensor is in an inverse proportional function relationship. When the R-Squared is above 0.9, the relationship between the both may be expressed by the following formula:

Rₛ=25.138V²−840.58V+7032.7

where Rₛ denotes the resistance values of the metal films of the grinding objects, and V denotes the sensed voltage values of the eddy current sensor.

It can be known that, the smaller the resistance values of the metal films of the grinding objects are, the smaller the sensed voltage values of the eddy current sensor are.

It is to be noted that, the correspondence between the resistance values of the metal films of the grinding objects and the output values of the eddy current sensor obtained in the above embodiment needs to be pre-stored in the CMP equipment, so that the CMP equipment monitors the output value of the eddy current sensor in real time and controls the grinding time.

Step 103: An output value of the eddy current sensor is acquired in real time, and a grinding task is stopped when the output value reaches the target output value.

In the CMP manufacturing process, the eddy current sensor detects the change of the magnetic field in real time to obtain an original electrical signal value of the metal film of the grinding object; and then, the thickness of the metal film of the grinding object and the sensed voltage of the eddy current sensor can be determined through processing and simulation by a computer in the CMP equipment.

After the target output value of the eddy current sensor corresponding to the target resistance value of the metal film of the grinding object set by the user is determined, the target output value is used as a monitoring point for stopping grinding, and the current output value of the eddy current sensor is compared with the target output value. When the current output value is equal to the target output value, the grinding apparatus is controlled to stop the grinding task. The controlling the grinding apparatus to stop the grinding task comprises: sending a stop instruction to the first motor and the second motor of the grinding apparatus.

It can be known from the above description that, in this embodiment, the grinding time is automatically regulated for each grinding object by using the real-time output value of the eddy current sensor of the CMP grinding table, comparing the real-time output value with the target output value and using the target output value as a signal for terminating CMP grinding. Compared with the fixed grinding time at present, the resistance values of the metal films of the grinding object after the CMP process are closer to the target resistance value, so that the grinding precision is improved.

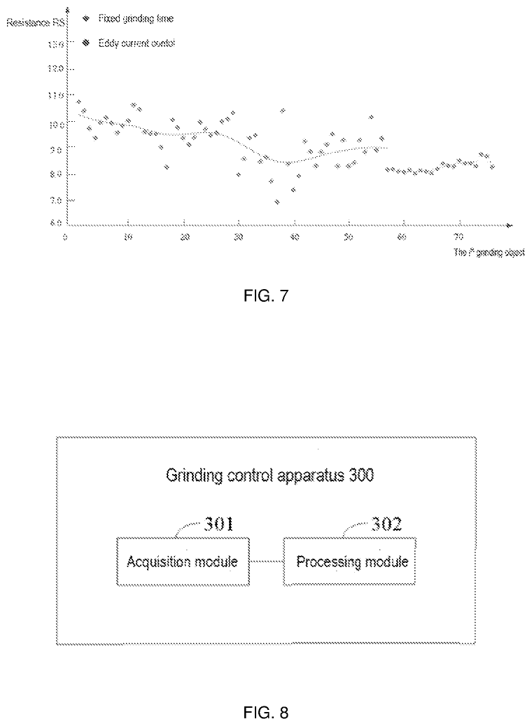

FIG. 7 is a schematic diagram of the distribution of the resistance value of the grinding object obtained by fixing the grinding time and automatically adjusting the grinding time in the present application. Each sampling point in FIG. 7 represents a grinding object sample, and the vertical coordinate corresponding to this sampling point represents the resistance value of the metal film of the grinding object sample after the CMP process. As shown in FIG. 7, the left curve is a distribution curve of the resistance value of the grinding object by fixing the grinding time, and the right curve is a distribution curve of the resistance value of the grinding object by automatically adjusting the grinding time in the present application. It can be known that: the resistance of the metal film of the grinding object obtained by grinding with the fixed grinding time is high in dispersion and unstable, so it is indicated that the grinding precision is low; and, the resistance of the metal film of the grinding object by controlling the grinding time though the CMP eddy current sensor is low in dispersion and always stable near the target resistance (±0.5 Ω/sq), so it is indicated that the resistance distribution is stable and the grinding precision is high. Accordingly, the yield and quality of products can be ensured by the technical solutions of the present application.

In addition, by the grinding control method in this embodiment, it is unnecessary to measure the thickness of the metal film of the grinding object during the grinding process, and the influence of the consumables of the equipment on the process stability is reduced. On the whole, the production cost is reduced, and the yield and quality of products are improved.

In the grinding control method provided in this embodiment, by using different grinding times for a plurality of grinding object samples, the output values of the eddy current sensor and the resistance values of the metal films of the grinding object samples at the end of CMP grinding are acquired, so that a monotonic relation curve of the output values of the eddy current sensor and the resistance values of the metal films of the grinding objects at the end of CMP is obtained. The target output value of the eddy current sensor at the end of CMP corresponding to the metal film grinding can be determined according to the target resistance value of the metal film in the chip design and in combination with the above curve, and a CMP grinding stop signal is set by using the target output value. According to the solution, the accurate control of the CMP grinding time of the metal film of each grinding object can be realized, and it is ensured to obtain stable resistance values in the electrical performance test of the metal films of the grinding objects.

In the embodiments of the present application, the functional modules of the grinding control apparatus can be divided according to the method embodiments. For example, each functional module may be divided for each function, or two or more functions may be integrated in one processing module. The integrated modules may be implemented in the form of hardware or software functional modules. It is to be noted that, the division of modules in the embodiments of the present application is schematic and merely a logic function division, and other division modes are also possible in actual implementations. The following description will be given by taking dividing each functional module for each function as an example.

FIG. 8 is a schematic diagram of the hardware structure of a grinding control apparatus according to an embodiment of the present application. As shown in FIG. 8, the grinding control apparatus 300 in this embodiment comprises:

an acquisition module 301, configured to acquire a target resistance value of a metal film of a grinding object set by a user; and

a processing module 302, configured to determine a target output value of an eddy current sensor according to the target resistance value; and

the acquisition module 301 is further configured to acquire an output value of the eddy current sensor in real time, and the processing module 302 is further configured to stop a grinding task when the output value reaches the target output value.

In one embodiment of the present application, the acquisition module 301 is further configured to a correspondence between the resistance values of the metal films of the grinding objects and the output values of the eddy current sensor; and

the processing module 302 is specifically configured to determine a target output value of the eddy current sensor according to the correspondence between the resistance value of the metal films of the grinding objects and the output value of the eddy current sensor and the target resistance value.

In one embodiment of the present application, the acquisition module 301 is specifically configured to acquire grinding test data sets of a plurality of grinding object samples, the grinding test data set of each of the grinding object samples comprising multiple groups of the resistance values of metal layers of the grinding object samples and the output values of the eddy current sensor; and

the processing module 302 is specifically configured to determine, according to the grinding test data sets of the plurality of grinding object samples, the correspondence between the resistance values of the metal films of the grinding objects and the output values of the eddy current sensor.

In one embodiment of the present application, the correspondence between the resistance values of the metal films of the grinding objects and the output values of the eddy current sensor is in an inverse proportional function relationship.

In one embodiment of the present application, the correspondence between the resistance values of the metal films of the grinding objects and the output values of the eddy current sensor is expressed as:

Rₛ=25.138V²−840.58V+7032.7

where Rₛ denotes the resistance values of the metal films of the grinding objects, and V denotes the output values of the eddy current sensor.

The grinding control apparatus according to the embodiment of the present application is used to execute the steps in the method embodiments, and its implementation principle and technical effects are similar and will not be repeated here.

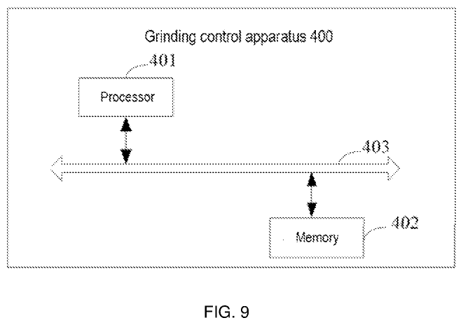

FIG. 9 is a schematic of the hardware diagram of a grinding control apparatus according to an embodiment of the present application. As shown in FIG. 9, the grinding control apparatus 400 in this embodiment comprises:

at least one processor 401 (only one processor is shown in FIG. 9); and

a memory 402 communicatively connected to the at least one processor, wherein,

the memory 402 is stored with instructions executable by the at least one processor 401 that, when executed by the at least one processor 401, enable the grinding control apparatus 400 to execute the steps in the method embodiments.

Optionally, the grinding control apparatus 400 may be integrated in a CMP equipment.

Optionally, the memory 402 may be independent, or may be integrated with the processor 401.

When the memory 402 is a device independent of the processor 401, the grinding control apparatus 400 further comprises: a bus 403, configured to connect the memory 402 and the processor 401.

The present application further provides a computer-readable storage medium having computer executable instructions stored therein that, when executed by a processor, implement the steps in the method embodiments.

The present application further provides a computer program product, comprising computer programs that, when executed by a processor, implement the technical solutions in the method embodiments.

An embodiment of the present application further provides a chip, comprising a processing module and a communication interface, wherein the processing module can execute the technical solutions in the method embodiments.

Further, the chip further comprises a storage module (e.g., a memory), wherein the storage module is configured to storage instructions, the processing module is configured to execute the instructions stored in the storage module, and the instructions stored in the storage module are executed to cause the processing module to execute the technical solutions in the method embodiments.

It should be understood that the processor mentioned in the embodiment of the present application may be central processing units (CPUs), or other general-purpose processors, digital signal processors (DSPs), application specific integrated circuits (ASICs), field programmable gate arrays (FPGAs) or other programmable logic devices, discrete gates or transistor logic devices, discrete hardware components, etc. The general-purpose processors may be microprocessors, or the processor may be any conventional processor, etc.

It should be further understood that the memory mentioned in the embodiment of the present application may be volatile memories or nonvolatile memories, or may comprise volatile memories and nonvolatile memories. The nonvolatile memories may be read-only memories (ROMs), programmable ROMs (PROMs), erasable PROMs (EPROMs), electrically EPROMs (EEPROMs) or flash memories. The volatile memories may comprise random access memories (RAMs), which are used as external caches. By way of example but not limiting, RAMs in various forms are available, for example, static RAMs (SRAMs), dynamic RAMs (DRAMs), synchronous DRAMs (SDRAMs), double data rate SDRAMs (DDR SDRAMs), enhanced SDRAMs (ESDRAMs), synchlink DRAMs (SLDRAMs) and direct Rambus RAMs (DR RAMs).

The bus may be industry standard architecture (ISA) buses, peripheral component (PCI) buses or extended industry standard architecture (EISA) buses, etc. The bus may be classified into address buses, data buses, control buses, etc. For convenience of representation, the bus in the drawings of the present application is not limited to only one bus or one type of buses.

It is to be noted that, when the processor is a general-purpose processor, a DSP, an ASIC, an FPGA or other programmable logic devices, a discrete gate or transistor logic device, or a discrete hardware component, the memory (storage module) is integrated in the processor.

It is to be noted that the memory described herein is intended to include, but not limited to, memories of these types and memories of any other suitable types.

It should be understood that, in various embodiments of the present application, the serial numbers of the processes does not mean the order of execution, and the order of execution of the processes shall be determined by their functions and internal logics and does not constitute any limitation to the implementation of the embodiments of the present application.

The above description merely shows the specific implementations of the present application, and the protection scope of the present application is not limited thereto. Any variation or replacement easily obtained by any person of ordinary skill in the art without departing from the technical scope of the present application should be included within the protection scope of the present disclosure. Therefore, the protection scope of the present application shall be subject to the protection scope defined by the claims.

1. A grinding control method, comprising:
acquiring a target resistance value of a metal film of a grinding object set by a user;
determining a target output value of an eddy current sensor according to the target resistance value; and
acquiring an output value of the eddy current sensor in real time, and stopping a grinding task when the output value reaches the target output value.

2. The method according to claim 1, wherein the determining a target output value of an eddy current sensor according to the target resistance value comprises:
acquiring a correspondence between resistance values of the metal films of the grinding objects and output values of the eddy current sensor; and
determining a target output value of the eddy current sensor according to the correspondence between the resistance values of the metal films of the grinding objects and the output values of the eddy current sensor and the target resistance value.

3. The method according to claim 2, wherein the acquiring a correspondence between resistance values of the metal films of the grinding objects and output values of the eddy current sensor comprises:
acquiring grinding test data sets of a plurality of grinding object samples, the grinding test data set of each of the grinding object samples comprising multiple groups of the resistance values of metal films of the grinding object samples and the output values of the eddy current sensor; and
determining, according to the grinding test data sets of the plurality of grinding object samples, the correspondence between the resistance values of the metal films of the grinding objects and the output values of the eddy current sensor.

4. The method according to claim 2, wherein the correspondence between the resistance values of the metal films of the grinding objects and the output values of the eddy current sensor is in an inverse proportional function relationship.

5. The method according to claim 4, wherein the correspondence between the resistance values of the metal films of the grinding objects and the output values of the eddy current sensor is expressed as:
Rₛ=25.138V²−840.58V+7032.7
where Rₛ denotes the resistance values of the metal films of the grinding objects, and V denotes the output values of the eddy current sensor.

6. A grinding control apparatus, comprising:
an acquisition module, configured to acquire a target resistance value of a metal film of a grinding object set by a user; and
a processing module, configured to determine a target output value of an eddy current sensor according to the target resistance value; and
the acquisition module is further configured to acquire an output value of the eddy current sensor in real time, and the processing module is further configured to stop a grinding task when the output value reaches the target output value.

7. The apparatus according to claim 6, wherein the acquisition module is further configured to a correspondence between resistance values of the metal films of the grinding objects and output values of the eddy current sensor; and
the processing module is configured to determine a target output value of the eddy current sensor according to the correspondence between the resistance values of the metal films of the grinding objects and the output values of the eddy current sensor and the target resistance value.

8. The apparatus according to claim 7, wherein the acquisition module is configured to acquire grinding test data sets of a plurality of grinding object samples, the grinding test data set of each of the grinding object samples comprising multiple groups of the resistance values of metal films of the grinding object samples and the output values of the eddy current sensor; and
the processing module is configured to determine, according to the grinding test data sets of the plurality of grinding object samples, the correspondence between the resistance values of the metal films of the grinding objects and the output values of the eddy current sensor.

9. The apparatus according to claim 7, wherein the correspondence between the resistance values of the metal films of the grinding objects and the output values of the eddy current sensor is in an inverse proportional function relationship.

10. The apparatus according to claim 9, wherein the correspondence between the resistance values of the metal films of the grinding objects and the output values of the eddy current sensor is expressed as:
Rₛ=25.138V²−840.58V+7032.7
where Rₛ denotes the resistance values of the metal films of the grinding objects, and V denotes the output values of the eddy current sensor.

11. A grinding control apparatus, comprising:
at least one processor; and
a memory communicatively connected to the at least one processor, wherein,
the memory is stored with instructions executable by the at least one processor that, when executed by the at least one processor, enable the grinding control apparatus to execute the method according to claim 1.
